(19) United States
(12) Patent Application Publication
(10) Pub. No.: US 2024/0074274 A1
(43) Pub. Date: Feb. 29, 2024

(54) DISPLAY DEVICE AND MANUFACTURING METHOD THEREOF

(71) Applicant: Samsung Display Co., LTD., Yongin-si (KR)

(72) Inventor: Da-Hee JEONG, Yongin-si (KR)

(73) Assignee: Samsung Display Co., LTD., Yongin-si (KR)

(21) Appl. No.: 18/341,949

(22) Filed: Jun. 27, 2023

(30) Foreign Application Priority Data
Aug. 24, 2022 (KR) 10-2022-0106200

(51) Int. Cl. H10K 59/35; G06V 40/13; H10K 39/34; H10K 59/12

(52) U.S. Cl. CPC H10K 59/353; G06V 40/1318; H10K 39/34; H10K 59/1201; G09G 3/32

(57) ABSTRACT

A display device according to an embodiment includes a plurality of blue pixels, a plurality of red pixels, a plurality of green pixels, and a plurality of optical sensing pixels that are positioned on a substrate, wherein one of the plurality of optical sensing pixels is positioned between two of the plurality of green pixels in a first direction, and one of the optical sensing pixels is positioned between two of the plurality of green pixels in a second direction that is perpendicular to the first direction.

### CROSS-REFERENCE TO RELATED APPLICATION

This application claims priority to and the benefit of Korean Patent Application No. 10-2022-0106200 under 35 U.S.C. § 119, filed in the Korean Intellectual Property Office (KIPO) on Aug. 24, 2022, the entire contents of which are incorporated herein by reference.

### BACKGROUND

### 1. Technical Field

The disclosure relates to a display device and a manufacturing method thereof, and more specifically, it relates to a display device that can detect a biometric fingerprint input and a manufacturing method thereof.

### 2. Description of the Related Art

Multimedia display devices such as televisions, portable phones, tablet computers, navigation devices, and game machines have display devices for displaying images. The display devices may have an input detection panel that can provide a touch-based input method that allows users to readily and conveniently input information or instructions in addition to conventional input methods such as a button, a keyboard, and a mouse.

Recently, as a user authentication method for online banking, product purchase, security, and the like, a method of using a fingerprint, which is a type of biometric information, has been proposed, and a demand for a touch display device having a fingerprint recognition function is increasing.

As the fingerprint recognition function is added, pixel integration increases.

The above information disclosed in this Background section is only for enhancement of understanding of the background of the invention, and therefore it may contain information that does not form the prior art that is already known in this country to a person of ordinary skill in the art.

### SUMMARY

Embodiments are intended to provide a display device that can detect user biometric fingerprint information and display image information, and a manufacturing method thereof.

It should be noted that objects of the disclosure are not limited to the above-described objects, and other objects of the disclosure will be apparent to those skilled in the art from the following descriptions.

A display device according to an embodiment includes a plurality of blue pixels, a plurality of red pixels, a plurality of green pixels, and a plurality of optical sensing pixels that are positioned on a substrate, wherein one of the plurality of optical sensing pixels is positioned between two of the plurality of green pixels in a first direction, and one of the plurality of optical sensing pixels is positioned between two of the plurality of green pixels in a second direction that is perpendicular to the first direction.

One of the plurality of green pixels may be positioned between one of the plurality of blue pixels and one of the plurality of the red pixels in the first direction.

One of the plurality of green pixels may be positioned between one of the plurality of blue pixels and the plurality of red pixels in the second direction.

Each of the plurality of green pixels may be positioned adjacent to another one of the plurality of green pixels in the first direction or the second direction.

Emission layers of neighboring ones of the plurality of green pixels may be connected with each other.

An opening of each of the plurality of blue pixels, the plurality of green pixels, the plurality of red pixels, and the optical sensing pixels may have an octagonal shape.

The plurality of optical sensing pixels, and the plurality of red pixels and the plurality of blue pixels may not be positioned on a same line in the first direction, and the plurality of optical sensing pixels, and the plurality of red pixels and the plurality of blue pixels may not be positioned on a same line in the second direction.

A display device according to an embodiment includes a plurality of units that are iteratively positioned on a substrate, wherein each of the plurality of units comprises four green pixels, two red pixels, two blue pixels, and one optical sensing pixel, the optical sensing pixel may be positioned at a center of each of the plurality of units, two of the four green pixels and the optical sensing pixel may be positioned on a same line in a first direction, and two of the four green pixels and the optical sensing pixel may be positioned on a same line in a second direction that is perpendicular to the first direction.

Each of the plurality of units may be formed in a shape of a quadrangle, the two red pixels and the two blue pixels may be positioned at a corner of the each of the plurality of units, the two red pixels may be positioned in a diagonal direction with the optical sensing pixel in between, and the two blue pixels may be positioned in a diagonal direction with the optical sensing pixel in between.

The two red pixels, the four green pixels, and the two blue pixels may be positioned on each side of the each of the plurality of units.

One of the four green pixels of one of the plurality of units may be positioned adjacent to one of the four green pixels of another one of the plurality of units in the first direction or the second direction.

Emission layers of adjacent green pixels may be connected with each other.

An opening of each of the two blue pixels, the four green pixels, the two red pixels, and the optical sensing pixel may be formed in the shape of an octagon.

A manufacturing method of a display device according to an embodiment includes preparing a plurality of green pixels and a plurality of optical sensing pixels positioned on a substrate; and forming an emission layer of the plurality of green pixels, one of the plurality of optical sensing pixels may be positioned between two of the plurality of green pixels in a first direction, one of the plurality of optical sensing pixels may be positioned between two of plurality of green pixels in a second direction that is perpendicular to the first direction, and in the forming of the emission layer of the plurality of green pixels, the emission layer of adjacent one ones of the plurality of green pixels may be formed using one mask opening.

Emission layers of the plurality of green pixels adjacent to each other may be connected with each other.

The method may further include preparing a plurality of blue pixels and a plurality of red pixels on the substrate.

The manufacturing method of the display device may further include forming a hole transport layer of the plurality of optical sensing pixels and a hole control layer of the plurality of red pixels, wherein the hole transport layer of the plurality of optical sensing pixels and the hole control layer of the plurality of red pixels may be formed using one mask.

A size of an opening corresponding to the plurality of red pixels of the mask may be greater than a size of an opening corresponding to the plurality of optical sensing pixels.

One of the plurality of green pixels may be positioned between one of the plurality of blue pixels and one of the plurality of red pixels in the first direction.

The plurality of optical sensing pixels, and the plurality of red pixels and the plurality of blue pixels may not be positioned on a same line in the first direction, and the plurality of optical sensing pixels, and the plurality of red pixels and the plurality of blue pixels may not be positioned on a same line in the second direction.

According to embodiments, a display device that can display image information and detect user biometric fingerprint information and a manufacturing method thereof are provided.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows an arrangement of a light emitting pixel and an optical sensing pixel on a plane in a display device according to an embodiment;

FIG. 2 shows a configuration that the unit of FIG. 1 is iteratively arranged;

FIG. 3 is a schematic cross-sectional view of FIG. 1, taken along line of FIG. 1;

FIG. 4 shows a configuration for depositing neighboring green pixels G using respective mask openings;

FIG. 5 shows a configuration of depositing neighboring green pixels using one mask opening according to an embodiment;

FIG. 6 is a schematic cross-section of FIG. 5, taken along line VI-VI′ of FIG. 5;

FIG. 7 shows a mask for simultaneously forming a hole control layer of a red pixel and a hole transport layer of an optical sensing pixel;

FIG. 8 shows an embodiment in which a size of a second opening overlapping the optical sensing pixel is smaller than a size of a first opening overlapping the red pixel;

FIG. 9 shows a schematic diagram of an equivalent circuit of a configuration of the optical sensing pixel;

FIG. 10 is a schematic timing diagram to illustrate an operation of the optical sensing pixel shown in FIG. 9;

FIG. 11 is a schematic diagram of an equivalent circuit of a light emitting pixel PX according to an embodiment;

### DETAILED DESCRIPTION OF THE EMBODIMENTS

Hereinafter, various embodiments of the disclosure will be described in detail with reference to the accompanying drawing, and thus a person of an ordinary skill can readily perform it in the technical field to which the disclosure belongs. The disclosure may be implemented in several different forms and is not limited to the embodiments described herein.

In order to clearly explain the disclosure, parts irrelevant to the description are omitted, and the same reference sign is designated to the same or similar constituent elements throughout the specification.

In addition, since the size and thickness of each component shown in the drawing are arbitrarily indicated for better understanding and ease of description, the disclosure is not necessarily limited to the drawings. In the drawings, the thickness of layers, films, panels, regions, etc., may be exaggerated for clarity. In addition, in the drawings, the thicknesses of some layers and regions may be exaggerated for better understanding and ease of description.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

In addition, unless explicitly described to the contrary, the word “comprise”, and variations such as “comprises” or “comprising”, will be understood to imply the inclusion of stated elements but not the exclusion of any other elements.

Further, throughout the specification, the word “on” a target element will be understood to mean positioned above or below the target element, and will not necessarily be understood to mean positioned “at an upper side” based on an opposite to gravity direction.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, a display device according to an embodiment of the disclosure, and a manufacturing method thereof will be described in detail with reference to the accompanying drawings.

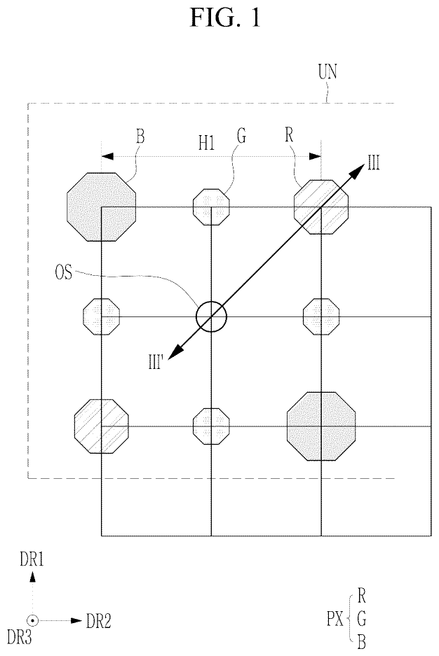

FIG. 1 illustrates an arrangement of a light emitting pixel PX and an optical sensing pixel OS in a plan view in a display device according to the embodiment. Referring to FIG. 1, a light emitting pixel PX may include a light emitting element for light emission. Specifically, the light emitting pixel PX may include a red pixel R, a green pixel G, and a blue pixel B. The red pixel R may emit red light, the green pixel G may emit green light, and the blue pixel B may emit blue light. The optical sensing pixel OS may include an optical sensing element and sense external light. These optical sensing pixels OS may recognize fingerprints by sensing external light. For example, the fingerprint may be recognized by sensing light reflected by ridges or valleys between the ridges of the fingerprint.

FIG. 1 illustrates each of the light emitting pixels PX and the optical sensing pixel with an opening of the pixel as a reference. In this case, as shown in FIG. 1, the shape of the opening of each pixel may be octagonal. This is a structure to make the separation distance of each pixel as far as possible, and the distance between pixels can be widened compared to the case where the shape of the opening of the pixel is a quadrangle. Therefore, deposition using a mask is possible on a high-resolution display device. However, this is an example, and the shape of the opening of each pixel may be a quadrangular or other shape according to an embodiment.

As shown in FIG. 1, a display device according to the embodiment may include a light emitting pixel PX that emits colored light and an optical sensing pixel OS that detects light, and can sense external light and detect fingerprints. Since the optical sensing pixel OS is positioned in this way, the process margin may be insufficient in a same resolution compared to a display device that does not include an optical sensing pixel OS. For example, since the number of pixels to be disposed in a same area increases in case that optical sensing pixels OS are included compared to when optical sensing pixels are not included, resolution may be deteriorated or it is difficult to design efficient arrangement and the aperture ratio may be lowered.

The disclosure relates to an efficient arrangement design of the display device including such an optical sensing pixel OS.

FIG. 1 illustrates a unit UN that is the minimum repeating unit of pixel arrangement in a display device according to the embodiment. Referring to FIG. 1, the unit UN may include two red pixels R, two blue pixels B, four green pixels G, and an optical sensing pixel OS. In the unit UN shown in FIG. 1, the red pixel R may be positioned on the diagonal edge of the quadrangle that forms the unit UN. The blue pixel B may be positioned on the other diagonal edge of the quadrangle that forms the unit UN. For example, in FIG. 1, two red pixels R and two blue pixels B are positioned at the four vertices of the quadrangle forming the unit UN.

The green pixel G may be positioned between the next red pixel R and the blue pixel B. For example, the green pixel G can be positioned at the center of each side of the quadrangle forming the unit UN.

The optical sensing pixel OS may be positioned at the center of the quadrangle forming the unit UN. The green pixel G may be positioned above and below of the optical sensing pixel OS in a first direction DR1. The green pixel G may be positioned on the left and right of the optical sensing pixel OS in a second direction DR2. For example, the arrangement according to the embodiment may be a structure in which four green pixels G are positioned up, down, left, and right with an optical sensing pixel OS as a reference, and two red pixels R and two blue pixel B are positioned in a diagonal direction.

A length H1 of a unit UN may be about ⅔ of a length of about 2 pitches in a normal arrangement. For example, in a display device having a resolution of about 496 ppi, a length of 1 pitch of a typical arrangement may be about 25.4 mm/496=about 0.0512 mm Therefore, the length of 2 pitches may be about 0.1024 nm, and the length H1 of a unit UN may be about 0.683 mm in a display device with an about 496 ppi resolution. However, this is an example, and the disclosure is not limited thereto.

Such a structure can efficiently arrange optical sensing pixels OS while maintaining the aperture ratio of the display device.

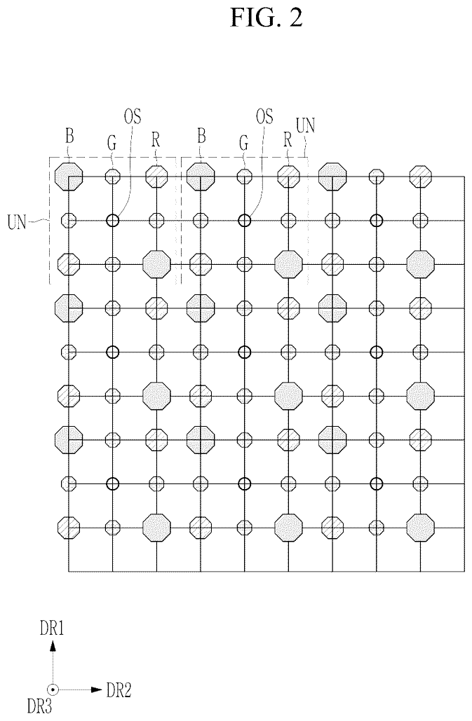

FIG. 2 illustrates a configuration that the unit UN of FIG. 1 is iteratively arranged. Referring to FIG. 2, a structure in which the unit UN of FIG. 1 is repeatedly arranged can be confirmed. For example, the display device according to the embodiment may have an arrangement in which four green pixels G are positioned up, down, left, and right with an optical sensing pixel OS as a reference, and the unit UN in which two red pixels R and two blue pixels B are positioned in the diagonal direction is repeated.

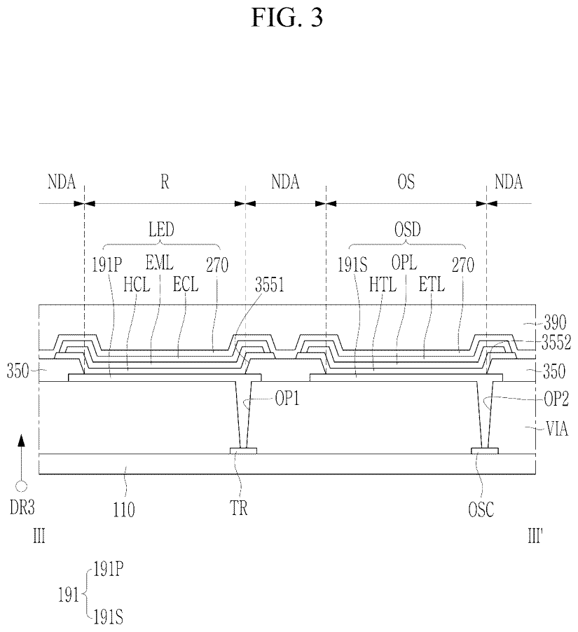

FIG. 3 is a schematic cross-sectional view of FIG. 1, taken along line FIG. 3 briefly illustrates a cross-section of the display device according to the embodiment. Referring to FIG. 3, a transistor TR and an optical sensing circuit OSC that are positioned on a substrate 110 may be included. FIG. 3 illustrates the red pixel R, the optical sensing pixel OS, and a non-emission area NDA.

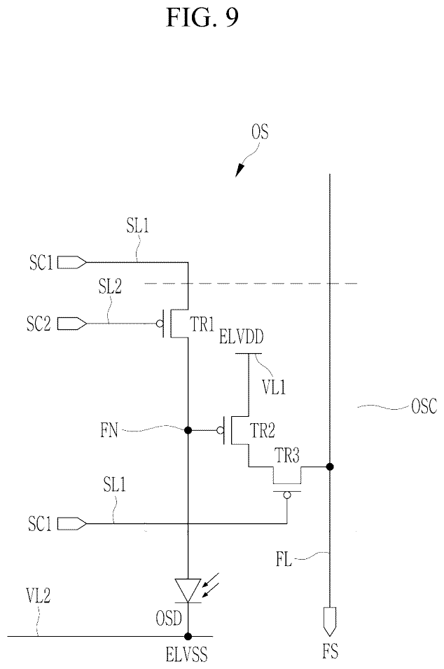

The transistor TR may transmit a driving signal and a voltage for driving a light emitting diode LED. The optical sensing circuit OSC may sense light through photocharges generated by an optical sensing element OSD. The transistor TR and the optical sensing circuit OSC may include a semiconductor and wires including gate lines and data lines. The detailed operation of the transistor TR and the optical sensing circuit OSC will be described below in detail with reference to FIGS. 9 to 11.

An insulating layer VIA may be positioned on the transistor TR and the optical sensing circuit OSC. The insulating layer may include an organic material. Specifically, the insulating layer VIA may include organic insulating materials such as general-purpose polymers such as polymethylmethacrylate (PMMA) or polystyrene (PS), polymer derivatives with phenolic groups, acryl-based polymers, imide-based polymers, polyimide, and siloxane-based polymers. However, the embodiments are not limited thereto.

A first electrode 191 may be positioned on the insulating layer VIA. The first electrode 191 may include a first light emitting electrode 191P of a light emitting diode LED and a first sensing electrode 191S of the optical sensing element OSD. The insulating layer VIA may include a first opening OP1 and a second opening OP2. The first light emitting electrode 191P of the light emitting diode LED may be electrically connected to the transistor TR through the first opening OP1, and the first sensing electrode 191S of the optical sensing element OSD may be electrically connected to the optical sensing circuit OSC through the second opening OP2. The first light emitting electrode 191P and the first sensing electrode 191S may be formed by a same process and include a same material.

A partitioning wall 350 may be positioned on the first light emitting electrode 191P and the first sensing electrode 191S. The partitioning wall 350 may include a first opening 3551 overlapping the first light emitting electrode 191P and a second opening 3552 overlapping the first sensing electrode 191S (e.g., in a third direction DR3 or in a plan view).

A hole control layer HCL may be positioned within the first opening 3551 overlapping the first light emitting electrode 191P. An emission layer EML may be positioned on the hole control layer HCL, and an electron control layer ECL may be positioned on the emission layer EML. The hole control layer HCL may include a hole injection layer and a hole transport layer. Similarly, the electron control layer ECL may include an electron injection layer and an electron transport layer. The emission layer EML may emit blue, green, and red light in each pixel. The emission layer EML may have a structure in which emission layers emitting light of different colors are stacked each other.

A hole transport layer HTL may be positioned within the second opening 3552 overlapping the first sensing electrode 191S. The hole transport layer HTL and hole control layer HCL of the light emitting element may be formed of a same material and by a same process. A photoelectric conversion layer OPL may be positioned on the hole transport layer HTL. The photoelectric conversion layer OPL may generate photocharges corresponding to the light reflected by the ridges of the fingerprint or the valleys between the ridges of the fingerprint and may transmit them to the optical sensing circuit OSC. An electron transport layer ETL may be positioned on the photoelectric conversion layer OPL.

Although described separately below, the hole control layer HCL and electron control layer ECL of the light emitting pixel PX and the hole transport layer HTL and the electron transport layer ETL of the optical sensing pixel OS may be formed by a same process, and may include a same material.

A second electrode 270 may be positioned on the electron transport layer ETL and the electron control layer ECL. The second electrode 270 may be positioned as a whole over the optical sensing pixels OS and the light emitting pixels PX in a plate shape. In the light emitting pixel PX, a first light emitting electrode 191P, the hole control layer HCL, the emission layer EML, the electron control layer ECL, and the second electrode 270 may form the light emitting diode LED. In the optical sensing pixel OS, a first sensing electrode 191S, the hole transport layer HTL, the photoelectric conversion layer OPL, the electron transport layer ETL, and the second electrode 270 may form the optical sensing element OSD. A capping layer 390 may be positioned on the second electrode 270.

Referring to FIGS. 1 and 2, the arrangement of the pixels according to the embodiment may have a structure in which two green pixels G are adjacent to each other. Therefore, during deposition of a green emission layer in the manufacturing process, it can be deposited at once using a mask.

Hereinafter, a manufacturing method according to the embodiment will be described focusing on forming the light emitting diode LED and the optical sensing element OSD using a mask.

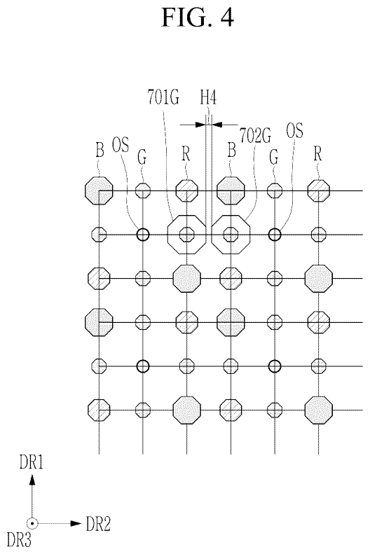

FIG. 4 illustrates a configuration for depositing neighboring green pixels G using respective mask openings 701G and 702G. FIG. 4 illustrates the openings 701G and 702G of the mask, for example, regions deposited by the mask. Referring to FIG. 4, in case that neighboring green pixels are deposited using masks with openings 701G and 702G, a distance H4 between the mask openings 701G and 702G must be secured for stable deposition. Therefore, the distance between the green pixels G must be greater than or equal to the minimum distance between the mask openings 701G and 702G, which limits the resolution.

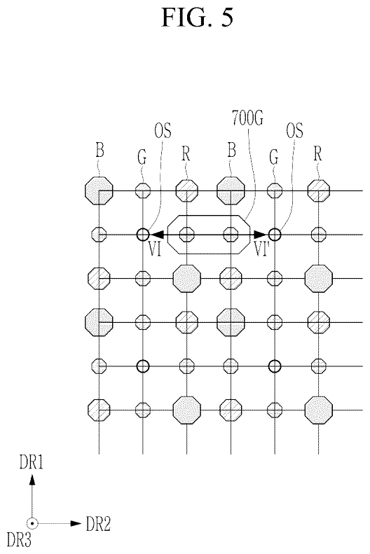

FIG. 5 illustrates a configuration of depositing neighboring green pixels G using a mask opening 700G according to the embodiment. FIG. 5 illustrates the opening 700G of the mask, for example, a region deposited by the mask. Referring to FIG. 5, as the two green pixels G are positioned adjacently, a green emission layer is deposited using a mask opening 700G. Unlike the embodiment of FIG. 4, there is no need to consider the minimum separation space between masks. Therefore, dense arrangement of pixels may be possible and high resolution can be implemented.

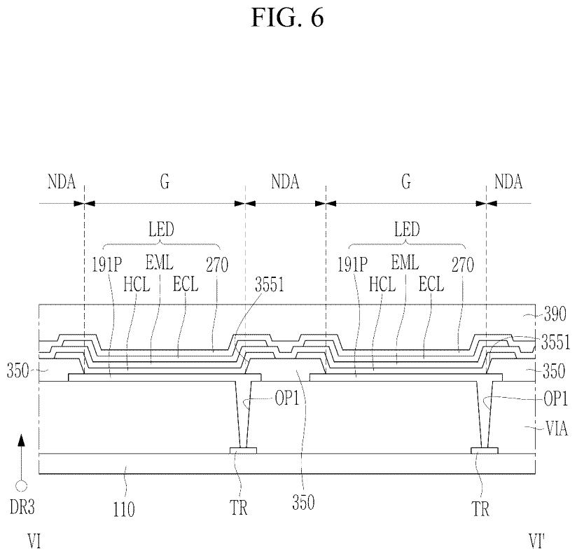

FIG. 6 is a cross-section of a display device in which two adjacent green pixels G are deposited as shown in FIG. 5 using a mask opening. FIG. 6 is a schematic cross-sectional view of FIG. 5, taken along line VI-VI′.

FIG. 6 is distinguishable from FIG. 3 at least in that an emission layer EML extends to neighboring green pixels as a single body, and thus a detailed description of the same constituent elements is omitted.

Referring to FIG. 6, it can be confirmed that the emission layer EML extends as a single one in the neighboring two green pixels G. This is because that, as shown in FIG. 5, the emission layer EML of the neighboring two green pixels G is formed simultaneously with a mask opening 700G. Although the emission layer EML extends in this way, since a separate electrode is not positioned on a partitioning wall 350 between the green pixels R, each green pixel G can emit light separately within a first opening 3551 of the partitioning wall 350.

FIG. 6 illustrates a configuration in which the emission layer EML is formed with a mask opening 700G in two adjacent green pixels G, but layers other than the emission layer EML may also be formed with a mask opening 700G. For example, in the two neighboring green pixels G, hole control layers HCL may be connected (and/or extended) to each other, or electron control layers ECL may be connected to each other.

The manufacturing method according to the embodiment may form a layer forming a light emitting pixel PX and an optical sensing pixel OS using a mask.

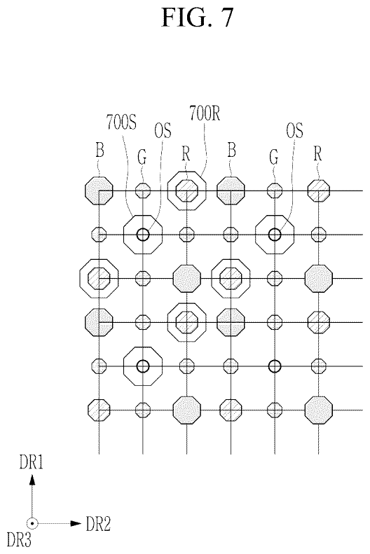

As described above, the hole control layer HCL of the light emitting pixel PX and the hole transport layer HTL of the optical sensing pixel OS may include a same material. FIG. 7 illustrates a mask for simultaneously forming the hole control layer HCL of the red pixel R and the hole transport layer HTL of the optical sensing pixel OS. Referring to FIG. 7, the mask according to the embodiment may include a first opening 700R overlapping a red pixel R and a second opening 700S overlapping the optical sensing pixel OS. Accordingly, the hole control layer HCL of the red pixel R and the hole transport layer HTL of the optical sensing pixel OS may be simultaneously formed using a mask. FIG. 7 illustrates as an example the red pixel R and the optical sensing pixel OS, but the same can be applied to other light emitting pixels and optical sensing pixels OS. In the above, the hole control layer HCL of the red pixel R and the hole transport layer HTL of the optical sensing pixel OS have been described as examples, but it can be applied to other layers forming each light emitting diode LED and optical sensing pixel OS.

Depending on embodiments, each light emitting diode LED and optical sensing element OSD may further include an auxiliary layer, and the auxiliary layer may also be formed simultaneously using a mask with openings such as the opening shown in FIG. 7.

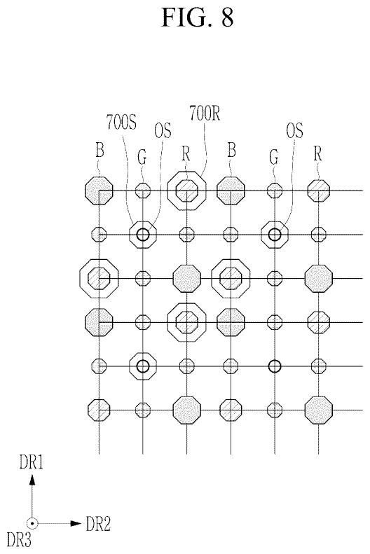

FIG. 7 illustrates that a size of the first opening 700R overlapping the red pixel R and a size of the second opening 700S overlapping the optical sensing pixel OS are the same, but the opening size may be different depending on embodiments. For example, the size of the optical sensing pixel OS may be smaller than that of the red pixel R, and the size of the second opening 700S overlapping the optical sensing pixel OS may be smaller than the size of the first opening 700R overlapping the red pixel R. FIG. 8 illustrates an embodiment in which the size of the second opening 700S overlapping the optical sensing pixel OS is smaller than the size of the first opening 700R overlapping the red pixel R.

Referring to FIG. 9, the operation of the optical sensing circuit OSC will be described.

FIG. 9 illustrates the circuit configuration of the optical sensing pixel OS. Referring to FIG. 9, the optical sensing pixel OS may include an optical sensing element OSD and an optical sensing circuit OSC. Referring to FIG. 9, the optical sensing circuit OSC may include a reset transistor TR1, an amplification transistor TR2, and an output transistor TR3. Each transistor may be a P-type transistor such as a PMOS, but is not limited thereto, at least one of the reset transistor TR1, the amplification transistor TR2, and the output transistor TR3 may be an N-type transistor.

The circuit configuration of the optical sensing element OSD according to the disclosure is not limited to FIG. 9. The optical sensing circuit OSC shown in FIG. 9 is an example, and the configuration of the optical sensing circuit OSC may be modified and implemented.

Referring to FIG. 9, an optical sensing pixel OS of a display device according to an embodiment may include a fingerprint detection line FL, a first scan line SL1, a second scan line SL2, a first voltage line VL1, a second voltage line VL2, a reset transistor TR1, an amplification transistor TR2, an output transistor TR3, and at least one optical sensing element OSD. In the embodiment, an example in which an optical sensing pixel OS may include an optical sensing element OSD is described.

A gate electrode of the reset transistor TR1 may be electrically connected to the second scan line SL2, a source electrode of the reset transistor TR1 may be electrically connected to the first scan line SL1, and a drain electrode of the reset transistor TR1 may be electrically connected to a charge storage node FN. The reset transistor TR1 may reset the charge storage node FN in response to a second scan signal SC2 transmitted through the second scan line SL2.

A gate electrode of the amplification transistor TR2 may be electrically connected to the charge storage node FN, a source electrode of the amplification transistor TR2 may be electrically connected to the first voltage line VL1, and a drain electrode of the amplification transistor TR2 may be electrically connected to a source electrode of the output transistor TR3. The amplification transistor TR2 may be turned on at a voltage level of the charge storage node FN and may transmit a first power source voltage EVLDD, transferred from the first voltage line VL1, to the source electrode of the output transistor TR3.

A gate electrode of the output transistor TR3 may be electrically connected to the first scan line SL1. The source electrode of the output transistor TR3 may be electrically connected to the drain electrode of the amplification transistor TR2.

The drain electrode of the output transistor TR3 may be electrically connected to the fingerprint detection line FL. The fingerprint detection line FL may transmit a fingerprint detection signal FS.

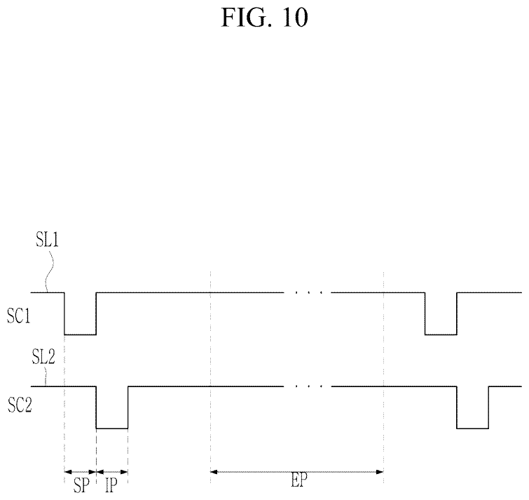

FIG. 10 is a schematic timing diagram to exemplarily describe the operation of the optical sensing pixel OS shown in FIG. 9.

During a light exposure period EP of the optical sensing pixel OS, the optical sensing element OSD may be exposed to external light. The optical sensing element OSD may use a charge as a main charge carrier.

In case that there is a user input, the optical sensing element OSD may generate photocharges corresponding to the light reflected by the ridges or the valleys between the ridges of the fingerprint, and the generated photocharges may be accumulated in the charge storage node FN.

The amplification transistor TR2 may be a source follower amplifier that generates a source-drain current in proportion to the charge amount of the charge storage node FN input to the gate electrode.

During a sensing period SP, a low-level first scan signal SC1 may be supplied through the first scan line SL1. In case that the output transistor TR3 is turned on in response to the low-level first scan signal SC1, a fingerprint detection signal FS corresponding to a current flowing through the amplification transistor TR2 can be output to the fingerprint detection line FL.

In case that a low-level second scan signal SC2 is supplied through the second scan line SL2 during an initialization period IP, the reset transistor TR1 may be turned on. Since a high-level first scan signal SC1 is provided to the source electrode of the reset transistor TR1, the high-level first scan signal SC1 may be transmitted to the charge storage node FN, and thus the charge storage node FN may be reset.

During the next light exposure period EP, the optical sensing element OSD may generate photocharges corresponding to the received external light, and the generated photocharges may be accumulated in the charge storage node FN.

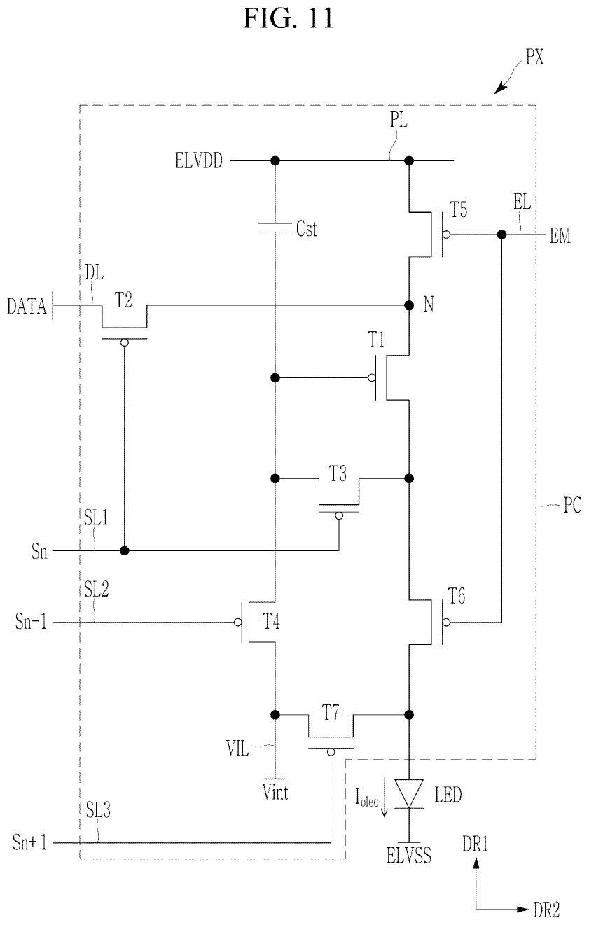

FIG. 11 is a schematic diagram of an equivalent circuit of a light emitting pixel PX according to an embodiment. The diagram shown in FIG. 11 is only an example, and the disclosure is not limited thereto.

Referring to FIG. 11, a pixel circuit PC may include first to seventh transistors T1 to T7, and the first to seventh transistors T1 to T7 may be implemented as thin-film transistors. The pixel circuit PC may transmit a first scan line SL1 transmitting a scan signal Sn, a second scan line SL2 transmitting a previous scan signal Sn−1, a third scan line SL3 transmitting a next scan signal Sn+1, a light emission control line EL transmitting a light emission control signal EM, and a data line DL transmitting a data signal DATA. The power source voltage line PL may transmit a first power source voltage ELVDD to the first transistor T1, and an initialization voltage line VIL may transmit an initialization voltage Vint that initializes the first transistor T1 and a light emitting diode LED to a gate electrode of the first transistor T1 and the light emitting diode LED. The first scan line SL1, the second scan line SL2, the third scan line SL3, the light emission control line EL, and the initialization voltage line VL may extend in the second direction DR2 and may be spaced apart from each other and arranged in each row. The data line DL and a power source voltage line PL may extend in the first direction DR1 and can be arranged at a distance from each other in each column. The first transistor T1 may be electrically connected to the power source voltage line PL via the fifth transistor T5 and be electrically connected to the light emitting diode LED via the sixth transistor T6. The first transistor T1 may be a driving transistor, and may receive the data signal DATA according to the switching operation of the second transistor T2 and may supply a driving current holed to the light emitting diode LED. The second transistor T2 may be electrically connected to the first scan line SL1 and the data line DL, and may be turned on according to the scan signal Sn received through the first scan line SL1 and may perform the switching operation to transmit the data signal DATA, transmitted to the data line DL, to a node N. The third transistor T3 may be electrically connected to the light emitting diode LED via the sixth transistor T6. The third transistor T3 may be turned on according to a first scan signal received through the first scan line SL1 and may electrically diode-connect the first transistor T1. The fourth transistor T4 may be turned on according to the previous scan signal Sn−1 received through the second scan line SL2, and may transmit the initialization voltage Vint, received from the initialization voltage line VIL, to a gate electrode of the first transistor T1 to initialize the gate voltage of the first transistor T1. The fifth transistor T5 and the sixth transistor T6 may be simultaneously turned on according to the light emission control signal EM received through the light emission control line EL and may thus form a current path such that a driving current holed can flow in a direction from the power source voltage line PL toward the light emitting diode LED. The seventh transistor T7 may be turned on according to the next scan signal Sn+1 received through the third scan line SL3 and may thus transmit the initialization voltage Vint, received from the initialization voltage line VIL, to the light emitting diode LED to initialize the light emitting diode LED. The seventh transistor T7 can be omitted. A capacitor Cst may be electrically connected to the power source voltage line PL and the gate electrode of the first transistor T1, and may store and maintain a voltage corresponding to the voltage difference between ends thereof, thereby maintaining the voltage applied to the gate electrode of the first transistor T1. The light emitting diode LED may include a pixel electrode and an opposite electrode, and the opposite electrode may receive a second power source voltage ELVSS. The light emitting diode LED may emit light by receiving the driving current holed from the first transistor T1, and may thus display an image. FIG. 11 illustrates that the seventh transistor T7 receives the next scan signal Sn+1 through the third scan line SL3, but the seventh transistor T7 may be electrically connected to the second scan line SL2 and may receive the previous scan signal Sn−1.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a plurality of blue pixels, a plurality of red pixels, a plurality of green pixels, and a plurality of optical sensing pixels that are positioned on a substrate, wherein
one of the plurality of optical sensing pixels is positioned between two of the plurality of green pixels in a first direction, and
one of the plurality of optical sensing pixels is positioned between two of the plurality of green pixels in a second direction that is perpendicular to the first direction.

2. The display device of claim 1, wherein one of the plurality of green pixels is positioned between one of the plurality of blue pixels and one of the plurality of red pixels in the first direction.

3. The display device of claim 1, wherein one of the plurality of green pixels is positioned between one of the plurality of blue pixels and the plurality of red pixels in the second direction.

4. The display device of claim 1, wherein each of the plurality of green pixels is positioned adjacent to another one of the plurality of green pixels in the first direction or the second direction.

5. The display device of claim 4, wherein emission layers of neighboring ones of the plurality of green pixels are connected with each other.

6. The display device of claim 1, wherein an opening of each of the plurality of blue pixels, the plurality of green pixels, the plurality of red pixels, and the plurality of optical sensing pixels has an octagonal shape.

7. The display device of claim 1, wherein
the plurality of optical sensing pixels, and the plurality of red pixels and the plurality of blue pixels are not positioned on a same line in the first direction, and
the plurality of optical sensing pixels, and the plurality of red pixels and the plurality of blue pixels are not positioned on a same line in the second direction.

8. A display device comprising:
a plurality of units that are iteratively positioned on a substrate, wherein
each of the plurality of units comprises four green pixels, two red pixels, two blue pixels, and one optical sensing pixel,
the optical sensing pixel is positioned at a center of each of the plurality of units,
two of the four green pixels and the optical sensing pixel are positioned on a same line in a first direction, and
two of the four green pixels and the optical sensing pixel are positioned on a same line in a second direction that is perpendicular to the first direction.

9. The display device of claim 8, wherein
each of the plurality of units is formed in a shape of a quadrangle,
the two red pixels and the two blue pixels are positioned at a corner of the each of the plurality of units,
the two red pixels are positioned in a diagonal direction with the optical sensing pixel in between, and
the two blue pixels are positioned in a diagonal direction with the optical sensing pixel in between.

10. The display device of claim 9, wherein
the two red pixels, the four green pixels, and the two blue pixels are positioned on each side of the each of the plurality of units.

11. The display device of claim 8, wherein
one of the four green pixels of one of the plurality of units is positioned adjacent to one of the four green pixels of another one of the plurality of units in the first direction or the second direction.

12. The display device of claim 11, wherein emission layers of adjacent green pixels are connected with each other.

13. The display device of claim 8, wherein
an opening of each of the two blue pixels, the four green pixels, the two red pixels, and the optical sensing pixel is formed in the shape of an octagon.

14. A manufacturing method of a display device, comprising
preparing a plurality of green pixels and a plurality of optical sensing pixels positioned on a substrate; and
forming an emission layer of the plurality of green pixels, wherein
one of the plurality of optical sensing pixels is positioned between two of the plurality of green pixels in a first direction,
one of the plurality of optical sensing pixels is positioned between two of the plurality of green pixels in a second direction that is perpendicular to the first direction, and
in the forming of the emission layer of the plurality of green pixels, the emission layer of adjacent ones of the plurality of green pixels are formed using one mask opening.

15. The manufacturing method of the display device of claim 14, wherein emission layers of the plurality of green pixels adjacent to each other are connected with each other.

16. The manufacturing method of the display device of claim 14, further comprising:
preparing a plurality of blue pixels and a plurality of red pixels on the substrate.

17. The manufacturing method of the display device of claim 16, further comprising:
forming a hole transport layer of the plurality of optical sensing pixels and a hole control layer of the plurality of red pixels,
wherein the hole transport layer of the plurality of optical sensing pixels and the hole control layer of the plurality of red pixels are formed using one mask.

18. The manufacturing method of the display device of claim 17, wherein a size of an opening corresponding to the plurality of red pixels of the mask is greater than a size of an opening corresponding to the plurality of optical sensing pixels.

19. The manufacturing method of the display device of claim 16, wherein one of the plurality of green pixels is positioned between one of the plurality of blue pixels and one of the plurality of red pixels in the first direction.

20. The manufacturing method of the display device of claim 16, wherein
the plurality of optical sensing pixels, and the plurality of red pixels and the plurality of blue pixels are not positioned on a same line in the first direction, and
the plurality of optical sensing pixels, and the plurality of red pixels and the plurality of blue pixels are not positioned on a same line in the second direction.
